(19) United States
(12) Patent Application Publication
(10) Pub. No.: US 2018/0213637 A1
(43) Pub. Date: Jul. 26, 2018

(54) PROCESS FOR PRODUCING WIRING SUBSTRATE

(71) Applicant: Asahi Glass Company, Limited, Chiyoda-ku (JP)

(72) Inventors: Tomoya HOSODA, Chiyoda-ku (JP); Toru SASAKI, Chiyoda-ku (JP); Nobutaka KIDERA, Chiyoda-ku (JP); Tatsuya TERADA, Chiyoda-ku (JP)

(73) Assignee: Asahi Glass Company, Limited, Chiyoda-ku (JP)

(21) Appl. No.: 15/925,990

(22) Filed: Mar. 20, 2018

Related U.S. Application Data
(63) Continuation of application No. PCT/JP2016/081171, filed on Oct. 20, 2016.

(30) Foreign Application Priority Data
Oct. 22, 2015 (JP) 2015-208154

(51) Int. Cl. H05K 1/02; H05K 1/11; H05K 1/03; H05K 3/00; H05K 3/42

(52) U.S. Cl. CPC H05K 1/0271; H05K 1/115; H05K 1/0373; H05K 3/0011; H05K 3/422; H05K 2201/0154; H05K 1/0393; H05K 2201/015; H05K 2201/068; H05K 2201/10098; H05K 2203/095; H05K 3/0014

(57) ABSTRACT

To provide a process for producing a wiring substrate with conduction failure in a hole formed in an electrical insulator layer suppressed even without conducting an etching treatment using metal sodium, and with unexpected deformation such as warpage suppressed even when the electrical insulator layer contains no woven fabric or non-woven fabric comprising reinforcing fibers. A process for producing a wiring substrate 1, which comprises forming a hole 20 in a laminate comprising a first conductor layer 12, an electrical insulator layer 10 which contains a specific fluororesin layer (A) 16 and a heat resistant resin layer (B) 18, contains no reinforcing fiber to substrate, and has a dielectric constant of from 2.0 to 3.5 and a linear expansion coefficient of from 0 to 35 ppm/° C., and a second conductor layer 14, applying, to an inner wall surface 20a of the hole 20, either one or both of a treatment with a permanganic acid solution and a plasma treatment without conducting an etching treatment using metal sodium, and then forming a plating layer 22 on the inner wall surface 20a of the hole 20.

### TECHNICAL FIELD

The present invention relates to a process for producing a wiring substrate.

### BACKGROUND ART

High-speed large-capacity radio communication is widely used for not only to information and communication terminals such as mobile phones but also automobiles, etc. In high-speed large-capacity radio communication, high frequency signals are transmitted by an antenna transmitting and receiving information. As an antenna, for example, a wiring substrate comprising an electrical insulator layer and a conductor layer formed on the electrical insulator layer is used. In the wiring substrate, in many cases, conductor layers are formed on both surfaces of the electrical insulator layer, and the conductor layers are electrically connected by a plating layer formed on an inner wall surface of a hole (through-hole) penetrating through the electrical insulator layer. Further, the antenna transmitting and receiving radio waves is, as the frequency of the radio waves becomes high for example, formed on a wiring substrate called e.g. a printed circuit board having an electronic circuit formed thereon, utilizing the wiring pattern of the electronic circuit in many cases.

The wiring substrate used for transmitting high frequency signals is required to have excellent transmission characteristics, that is, small transmission delay and small transmission loss. In order to improve the transmission characteristics, it is necessary to use, as an insulating material forming the electrical insulator layer, a material having a low dielectric constant and a low dielectric dissipation factor. As an insulating material having a low dielectric constant and a low dielectric dissipation factor, a fluororesin has been known. For example, a wiring substrate using as an insulating material e.g. polytetrafluoroethylene (PTFE) (Patent Document 1) or a wiring substrate using a fluororesin having acid anhydride residues (Patent Document 2) may be mentioned.

In a case where in a wiring substrate using a fluororesin as an insulating material, a hole is formed and a plating layer is formed on an inner wall surface of the hole, usually, in order to secure adhesion between the inner wall surface of the hole and the plating layer and to suppress conduction failure, a pre-treatment is applied to the inner wall surface of the hole and then a plating treatment is conducted. As a pre-treatment, an etching treatment with an etching liquid having metal sodium dissolved in tetrahydrofuran has been known. By such an etching treatment, the fluororesin on the inner wall surface of the hole is partially dissolved to roughen the inner wall surface, whereby adhesion between the inner wall surface of the hole and the plating layer will increase by the anchor effect. Further, fluorine atoms on the inner wall surface of the hole are replaced by e.g. hydroxy groups to lower water repellency, and accordingly the plating layer tends to be formed on the entire inner wall surface of the hole. However, metal sodium used for the etching treatment may ignite (explode) by contact with water, and great caution is needed for its handling and storage area. Further, since an organic solvent is used in a large amount, there are problems of health damage of an operator by intake, post-treatment, etc.

For a wiring substrate having conductor layers laminated on both sides of an electrical insulator layer, it is important to suppress unexpected deformation such as warpage on the substrate. To suppress unexpected deformation such as warpage, a method of incorporating woven fabric or non-woven fabric comprising glass fibers in an electrical insulator layer has been known (Patent Document 2). By the woven fabric or non-woven fabric, the linear expansion coefficient of the electrical insulator layer is brought to be closer to the linear expansion coefficient of the conductor layer, whereby unexpected deformation such as warpage on the resulting wiring substrate is suppressed. However, a wiring substrate using woven fabric or non-woven fabric has decreased flexibility and is thereby unsuitable for application as a flexible circuit board for which high flexibility is required.

### PRIOR ART DOCUMENTS

### Patent Documents

Patent Document 1: JP-A-2001-7466

Patent Document 2: JP-A-2007-314720

### DISCLOSURE OF INVENTION

### Technical Problem

It is an object of the present invention to provide a process for producing a wiring substrate capable of producing a wiring substrate with conduction failure in a hole formed in an electrical insulator layer suppressed even without conducting an etching treatment using metal sodium and with unexpected deformation such as warpage suppressed even when woven fabric or non-woven fabric comprising reinforcing fibers is not contained in the electrical insulator layer.

### Solution to Problem

The present invention has the following constitutions.

[1] A process for producing a wiring substrate comprising an electrical insulator layer, a first conductor layer formed on a first surface of the electrical insulator layer and a second conductor layer formed on a second surface opposite from the first surface of the electrical insulator layer, and having a hole which opens at least from the first conductor layer through the second conductor layer and having a plating layer formed on an inner wall surface of the hole; wherein

the electrical insulator layer has a multi-layered structure containing at least one fluororesin layer (A) containing a melt-moldable fluororesin (a) having at least one type of functional groups selected from the group consisting of carbonyl group-containing groups, hydroxy groups, epoxy groups and isocyanate groups, and at least one heat resistant resin layer (B) containing a heat resistant resin (b) (excluding the fluororesin (a)), contains no reinforcing fiber substrate made of woven fabric or non-woven fabric, and has a dielectric constant of from 2.0 to 3.5 and a linear expansion coefficient of from 0 to 35 ppm/° C.;

the process comprising forming the hole in a laminate comprising the first conductor layer, the electrical insulator layer and the second conductor layer; and

applying, to the inner wall surface of the hole formed, either one or both of a treatment with a permanganic acid solution and a plasma treatment without conducting an etching treatment using metal sodium, and then forming the plating layer on the inner wall surface of the hole.

[2] A process for producing a wiring substrate comprising an electrical insulator layer, a first conductor layer formed on a first surface of the electrical insulator layer and a second conductor layer formed on a second surface opposite from the first surface of the electrical insulator layer, and having a hole which opens at least from the first conductor layer through the second conductor layer and a plating layer formed on an inner wall surface of the hole; wherein

the electrical insulator layer has a multi-layered structure containing at least one fluororesin layer (A) containing a melt-moldable fluororesin (a) having at least one type of functional groups selected from the group consisting of carbonyl group-containing groups, hydroxy groups, epoxy groups and isocyanate groups, and at least one heat to resistant resin layer (B) containing a heat resistant resin (b) (excluding the fluororesin (a)), contains no reinforcing fiber substrate made of woven fabric or non-woven fabric, and has a dielectric constant of from 2.0 to 3.5 and a linear expansion coefficient of from 0 to 35 ppm/° C.;

the process comprising forming the hole in a laminate comprising the electrical insulator layer and the second conductor layer;

applying, to the inner wall surface of the hole formed, either one or both of a treatment with a permanganic acid solution and a plasma treatment without conducting an etching treatment using metal sodium, then forming the plating layer on the inner wall surface of the hole, and forming the first conductor layer on the first surface of the electrical insulator layer.

[3] The process for producing a wiring substrate according to [1] or [2], wherein the electrical insulator layer has a layer structure of heat resistant resin layer (B)/fluororesin layer (A), a layer structure of heat resistant resin layer (B)/fluororesin layer (A)/heat resistant resin layer (B) or a layer structure of fluororesin layer (A)/heat resistant resin layer (B)/fluororesin layer (A).
[4] The process for producing a wiring substrate according to any one of [1] to [3], wherein the fluororesin (a) has a melting point of at least 260° C.
[5] The process for producing a wiring substrate according to any one of [1] to [4], wherein the electrical insulator layer has a dielectric constant of from 2.0 to 3.0.
[6] The process for producing a wiring substrate according to any one of [1] to [5], wherein the functional groups contain at least carbonyl group-containing groups, and the carbonyl group-containing groups are at least one member selected from the group consisting of groups having a carbonyl group between carbon atoms in a hydrocarbon group, carbonate groups, carboxy groups, haloformyl groups, alkoxycarbonyl groups and acid anhydride residues.
[7] The process for producing a wiring substrate according to any one of [1] to [6], wherein the content of the functional groups in the fluororesin (a) is from 10 to 60,000 groups per 1×10⁶ carbon atoms in the main chain of the fluororesin (a).
[8] The process for producing a wiring substrate according to any one of [1] to [7], wherein the fluororesin (a) is composed of a copolymer of tetrafluoroethylene, a perfluoro(alkyl vinyl ether) and an unsaturated dicarboxylic anhydride.
[9] The process for producing a wiring substrate according to any one of [1] to [8], wherein the heat resistant resin (b) is composed of a polyimide.
[10] A wiring substrate comprising an electrical insulator layer, a first conductor layer formed on a first surface of the electrical insulator layer and a second conductor layer formed on a second surface opposite from the first surface of the electrical insulator layer, and having a hole which opens at least from the first conductor layer through the second conductor layer and a plating layer formed on an inner wall surface of the hole; wherein

the electrical insulator layer has a multi-layered structure containing at least one fluororesin layer (A) containing a melt-moldable fluororesin (a) having at least one type of functional groups selected from the group consisting of carbonyl group-containing groups, hydroxy groups, epoxy groups and isocyanate groups, and at least one heat resistant resin layer (B) containing a heat resistant resin (b) (excluding the fluororesin (a)), contains no reinforcing fiber substrate made of woven fabric or non-woven fabric, and has a dielectric constant of from 2.0 to 3.5 and a linear expansion coefficient of from 0 to 35 ppm/° C.; and

the following rate of change of electrical resistance as between before and after a thermal shock test is within a range of ±10%:

rate of change of electrical resistance: a rate of change of the resistance between the electrical insulator layers on both sides of the electrical insulator layer via the plating layer after a thermal shock test of conducting 100 cycles each comprising leaving the wiring substrate in an environment of −65° C. for 30 minutes and then leaving it in an environment of 125° C. for 30 minutes, based on the resistance before the thermal shock test.

[11] The wiring substrate according to [10], wherein the electrical insulator layer has a layer structure of heat resistant resin layer (B)/fluororesin layer (A), a layer structure of heat resistant resin layer (B)/fluororesin layer (A)/heat resistant resin layer (B) or a layer structure of fluororesin layer (A)/heat resistant resin layer (B)/fluororesin layer (A).
[12] An antenna, which comprises the wiring substrate as defined in [10] or [11], wherein at least one of the first conductor layer and the second conductor layer is a conductor layer having an antenna pattern.

### Advantageous Effects of Invention

According to the process for producing a wiring substrate of the present invention, it is possible to produce a wiring substrate with conduction failure in a hole formed in an electrical insulator layer suppressed even without conducting an etching treatment using metal sodium and with unexpected deformation such as warpage suppressed even when woven fabric or non-woven fabric comprising reinforcing fibers is not contained in the electrical insulator layer.

### BRIEF DESCRIPTION OF DRAWINGS

FIG. 1A is a cross-sectional view illustrating an example of a laminate used for a process for producing a wiring substrate of the present invention.

FIG. 1B is a cross-sectional view illustrating a state where a hole is formed in the laminate shown in FIG. 1A.

FIG. 1C is a cross-sectional view illustrating a state where a plating layer is formed on an inner wall surface of the hole in the laminate shown in FIG. 1B.

FIG. 2A is a cross-sectional view illustrating an example of a laminate used for a process for producing a wiring substrate of the present invention.

FIG. 2B is a cross-sectional view illustrating a state where a hole is formed in the laminate shown in FIG. 2A.

FIG. 2C is a cross-sectional view illustrating a state where a plating layer is formed on an inner wall surface of the hole in the laminate shown in FIG. 2B.

FIG. 3A is a cross-sectional view illustrating an example of a laminate used for a process for producing a wiring substrate of the present invention.

FIG. 3B is a cross-sectional view illustrating a state where a hole is formed in the laminate shown in FIG. 3A.

FIG. 3C is a cross-sectional view illustrating a state where a plating layer is formed on an inner wall surface of the hole in the laminate shown in FIG. 3B.

FIG. 4A is a cross-sectional view illustrating an example of a laminate used for a process for producing a wiring substrate of the present invention.

FIG. 4B is a cross-sectional view illustrating a state where a hole is formed in the laminate shown in FIG. 4A.

FIG. 4C is a cross-sectional view illustrating a state where a plating layer is formed on an inner wall surface of the hole in the laminate shown in FIG. 4B.

FIG. 4D is a cross-sectional view illustrating a state where a first conductor layer is formed on a first surface side of a fluororesin layer in the laminate shown in FIG. 4C.

FIG. 5A is a cross-sectional view illustrating an example of a laminate used for a process for producing a wiring substrate of the present invention.

FIG. 5B is a cross-sectional view illustrating a state where a hole is formed in the laminate shown in FIG. 5A.

FIG. 5C is a cross-sectional view illustrating a state where a plating layer is formed on an inner wall surface of the hole in the laminate shown in FIG. 5B.

FIG. 5D is a cross-sectional view illustrating a state where a first conductor layer is formed on a first surface side of a fluororesin layer in the laminate shown in FIG. 5C.

FIG. 6A is a cross-sectional view illustrating an example of a laminate used for a process for producing a wiring substrate of the present invention.

FIG. 6B is a cross-sectional view illustrating a state where a hole is formed in the laminate shown in FIG. 6A.

FIG. 6C is a cross-sectional view illustrating a state where a plating layer is formed on an inner wall surface of the hole in the laminate shown in FIG. 6B.

FIG. 6D is a cross-sectional view illustrating a state where a first conductor layer is formed on a first surface side of a fluororesin layer in the laminate shown in FIG. 6C.

### DESCRIPTION OF EMBODIMENTS

Meanings of the following terms in this specification are as follows.

A “heat resistant resin” means a polymer compound having a melting point of at least 280° C. or a polymer compound having a maximum allowable temperature as defined by JIS C4003:2010 (IEC 60085:2007) of at least 121° C.

The “melting point” means a temperature corresponding to the maximum value of the melting peak measured by differential scanning calorimetery (DSC) method.

“Melt-moldable” means having melt flowability.

“Having melt-flowability” means that a temperature at which the melt flow rate is from 0.1 to 1,000 g/10 min is present at a temperature higher by at least 20° C. than the melting point of the resin under a load of 49 N.

The “melt flow rate” means the melt mass flow rate (MFR) as defined in JIS to K7210:1999 (ISO1133:1997).

The “dielectric constant” of a fluororesin means a value measured by transformer bridge method in accordance with ASTM D150, in an environment at a temperature of 23° C.±2° C. under a relative humidity of 50%±5% RH, at a frequency of 1 MHz.

The “dielectric constant” of an electrical insulator layer means a value measured by split post dielectric resonator method (SPDR method) in an environment at 23° C.±2° C. under 50%±5% RH, at a frequency of 2.5 GHz.

In this specification, a unit derived from a monomer will sometimes be referred to as a monomer unit. For example, a unit derived from a fluorinated monomer will sometimes be referred to as a fluorinated monomer unit.

### [Wiring Substrate]

The wiring substrate to be produced by the production process of the present invention comprises an electrical insulator layer, a first conductor layer and a second conductor layer. The electrical insulator layer has a multi-layered structure containing at least one fluororesin layer (A) containing a melt-moldable fluororesin (A) having the after-described functional groups (Q) and at least one heat resistant resin layer (B) containing a heat resistant resin (b) (excluding the fluororesin (a)), contains no reinforcing fiber substrate made of woven fabric or non-woven fabric, and has a dielectric constant of from 2.0 to 3.5 and a linear expansion coefficient of from 0 to 35 ppm/° C. The first conductor layer is formed on a first surface of the electrical insulator layer, and the second conductor layer is formed on a second surface opposite from the first surface of the electrical insulator layer. The wiring substrate has a hole which opens at least from the first conductor layer through the second conductor layer and has a plating layer formed on an inner wall surface of the hole.

Hereinafter, the fluororesin layer (A) will sometimes be referred to as “layer (A)”, and the heat resistant resin layer (B) will sometimes be referred to as “layer (B)”. The arrangement of the layers in a direction from the first conductor layer to the second conductor layer in the wiring substrate or the electrical insulator layer will be represented by arranging the layers with “I” between layers.

The number of the layer (A) in the electrical insulator layer may be one or more. The number of the layer (B) in the electrical insulator layer may be one or more. The total number of the layer (A) and the layer (B) in the electrical insulator layer is preferably at most 5. Further, the layer (A) and the layer (B) are preferably arranged alternately, but are not necessarily arranged alternately.

The order of arrangement of the layer (A) and the layer (B) in the electrical insulator layer is preferably symmetrical in the direction of thickness of the electrical insulator layer with a view to suppressing unexpected deformation such as warpage. Specifically, for example, an electrical insulator layer comprising two layers (A) and one layer (B) preferably has a layer structure of layer (A)/layer (B)/layer (A). Further, an electrical insulator layer may have a layer structure of layer (B)/layer (A)/layer (B).

The order of arrangement in the electrical insulator layer is not limited to an order symmetrical in the thickness direction. For example, the electrical insulator layer may have a two layer structure of layer (A)/layer (B).

Further, the wiring substrate may have a resin layer on the opposite side of the first conductor layer from the electrical insulator layer or on the opposite side of the second conductor layer from the electrical insulator layer. The resin layer may, for example, be the layer (A) or the layer (B). Further, other conductor layer may further be formed on the opposite side of the first conductor layer from the electrical insulator layer or on the opposite side of the second conductor layer from the electrical insulator layer, via an adhesive layer or the resin layer.

The hole formed in the wiring substrate is not limited so long as it opens at least from the first conductor layer through the second conductor layer, and it does not necessarily penetrate from one surface of the wiring substrate through the other surface. For example, a hole which opens from the first conductor layer through the second conductor layer does not necessarily penetrate the first conductor layer or the second conductor layer.

As the wiring substrate to be produced by the production process of the present invention, for example, the following wiring substrates 1 to 3 may be mentioned.

A wiring substrate 1 comprises, as shown in FIG. 10, an electrical insulator layer 10, a first conductor layer 12 on a first surface 10a of the electrical insulator layer 10 and a second conductor layer 14 on a second surface 10b of the electrical insulator layer 10. The electrical insulator layer 10 has a three-layer structure of layer (A) 16/layer (B) 18/layer (A) 16. In the wiring substrate 1, a hole 20 which penetrates from the first conductor layer 12 through the second conductor layer 14 is formed, and a plating layer 22 is formed on an inner wall surface 20a of the hole 20.

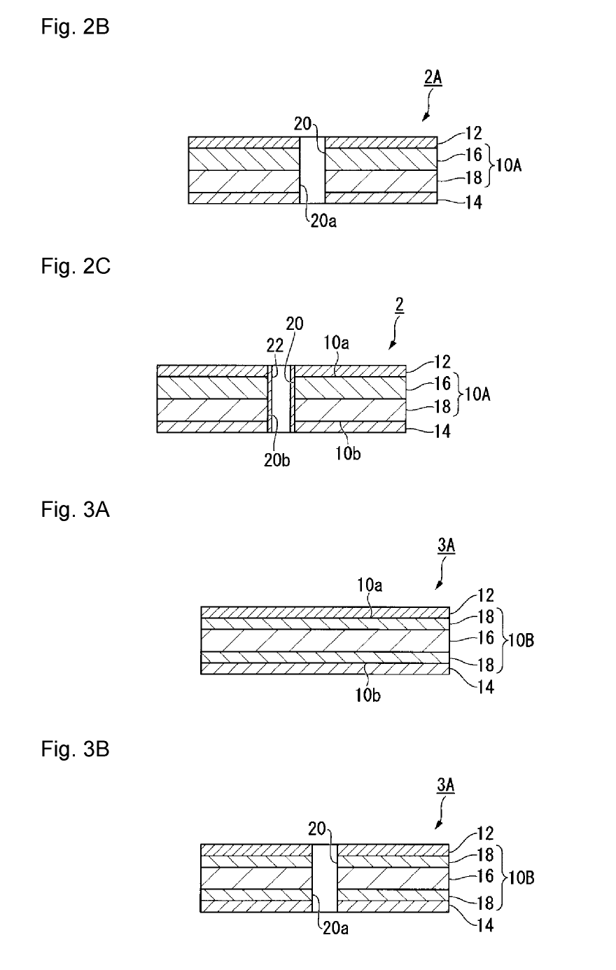

A wiring substrate 2 comprises, as shown in FIG. 2C, an electrical insulator layer 10A, a first conductor layer 12 on a first surface 10a of the electrical insulator layer 10A, and a second conductor layer 14 on a second surface 10b of the electrical insulator layer 10A. The electrical insulator layer 10A has a two layer structure of layer (A) 16/layer (B) 18. In the wiring substrate 2, a hole 20 which penetrates from the first conductor layer 12 through the second conductor layer 14 is formed, and a plating layer 22 is formed on an inner wall surface 20a of the hole 20.

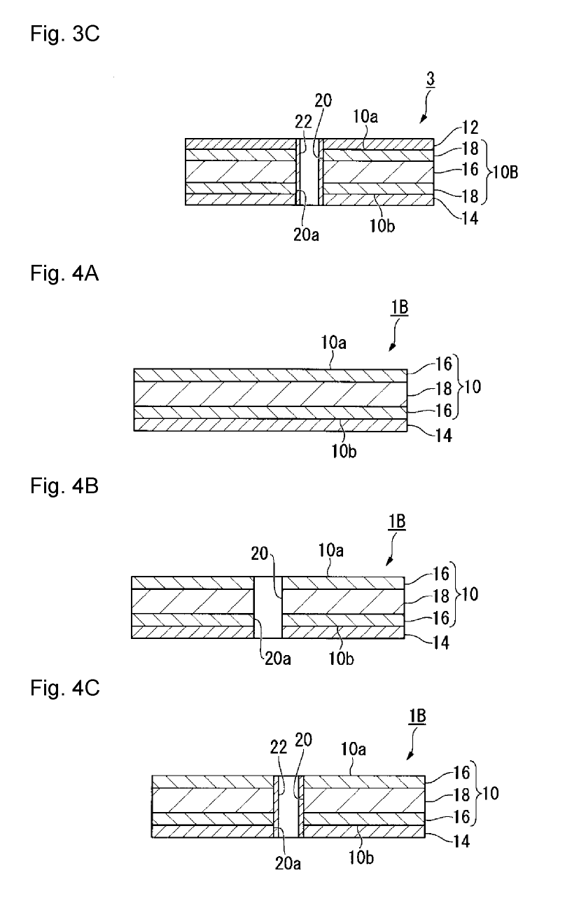

A wiring substrate 3 comprises, as shown in FIG. 3C, an electrical insulator layer 10B, a first conductor layer 12 on a first surface 10a of the electrical insulator layer 10B, and a second conductor layer 14 on a second surface 10b of the electrical insulator layer 10B. The electrical insulator layer 10B has a three layer structure of layer (B) 18/layer (A) 16/layer (B) 18. In the wiring substrate 3, a hole 20 which penetrates from the first conductor layer 12 through the second conductor layer 14 is formed, and a plating layer 22 is formed on an inner wall surface of the hole 20.

### (Electrical Insulator Layer)

The electrical insulator layer has a multi-layered structure containing at least one layer (A) and at least one layer (B), and contains no reinforcing fiber substrate made of woven fabric or non-woven fabric, such as glass cloth. By the electrical insulator layer containing no reinforcing fiber substrate, the wiring substrate obtained has excellent flexibility and is suitable as a flexible circuit board.

The dielectric constant of the electrical insulator layer is from 2.0 to 3.5, preferably from 2.0 to 3.0. When the dielectric constant of the electrical insulator layer is at most the above upper limit value, such a wiring substrate is useful for an application for which a low dielectric constant is required, such as an antenna. When the dielectric constant of the electrical insulator layer is at least the above lower limit value, both electrical characteristics and adhesion to the plating layer will be excellent.

The linear expansion coefficient of the electrical insulator layer is preferably from 0 to 35 ppm/° C., more preferably from 0 to 30 ppm/° C. When the linear expansion coefficient of the electrical insulator layer is at most the above upper limit value, the difference in the linear expansion coefficient with the conductor layer tends to be small, and unexpected deformation such as warpage on the wiring substrate tends to be to suppressed.

The linear expansion coefficient of the electrical insulator layer is determined by the method disclosed in Examples.

The thickness of the electrical insulator layer is preferably from 4 to 1,000 μm, more preferably from 6 to 300 μm. When the thickness of the electrical insulator layer is at least the above lower limit value, the wiring substrate will hardly be excessively deformed, whereby the conductor layer will hardly be disconnected. When the thickness of the electrical insulator layer is at most the above upper limit value, such a layer is excellent in flexibility and contributes to downsizing and weight saving of the resulting wiring substrate.

<Fluororesin layer (A)>

The layer (A) contains a melt-moldable fluororesin (a) having at least one type of functional groups selected from the group consisting of carbonyl group-containing groups, hydroxy groups, epoxy groups and isocyanate groups (hereinafter sometimes referred to as functional groups (Q)).

The thickness of the layer (A) is preferably from 2 to 300 μm, more preferably from 10 to 150 μm. When the thickness of the layer (A) is at least the above lower limit value, unexpected deformation such as warpage is likely to be suppressed. When the thickness of the layer (A) is at most the above upper limit value, such a layer is excellent in flexibility and contributes to downsizing and weight saving of the resulting wiring substrate.

<Fluororesin (a)>

The fluororesin (a) may, for example, be a fluororesin (a1) having units (1) having a functional group (Q) and units (2) derived from tetrafluoroethylene (TFE). The fluororesin (a1) may further have units other than the units (1) and the units (2) as the case requires.

The carbonyl group-containing group as the functional group (Q) may be any group which contains a carbonyl group in its structure and may, for example, be a group having a carbonyl group between carbon atoms in a hydrocarbon group, a carbonate group, a carboxy group, a haloformyl group, an alkoxycarbonyl group, an acid anhydride residue, a polyfluoroalkoxycarbonyl group or a fatty acid residue. Particularly, in view of excellent adhesion to a conductor layer or a plating layer, preferred is at least one to type selected from the group consisting of a group having a carbonyl group between carbon atoms in a hydrocarbon group, a carbonate group, a carboxy group, a haloformyl group, an alkoxycarbonyl group and an acid anhydride residue, more preferred is either one or both of a carboxy group and an acid anhydride residue.

In the group having a carbonyl group between carbon atoms in a hydrocarbon group, the hydrocarbon group may, for example, be a C2-8 alkylene group. The number of carbon atoms in the alkylene group is a number of carbon atoms not including the carbonyl group. The alkylene group may be linear or branched.

The halogen atom in the haloformyl group may, for example, be a fluorine atom or a chlorine atom and is preferably a fluorine atom.

The alkoxy group in the alkoxycarbonyl group may be linear or branched. The alkoxy group is preferably a C₁₋₈ alkoxy group, particularly preferably a methoxy group or an ethoxy group.

The number of the functional group (Q) in the unit (1) may be one or more. In a case where the unit (1) has two or more functional groups (Q), such functional groups (Q) may be the same or different.

The monomer containing a carbonyl group-containing group may, for example, be an unsaturated dicarboxylic acid anhydride which is a compound having an acid anhydride residue and a polymerizable unsaturated bond, a monomer having a carboxy group (such as itaconic acid or acrylic acid), a vinyl ester (such as vinyl acetate), a methacrylate or an acrylate (such as a (polyfluoroalkyl)acrylate), or CF₂═CFOR^{f1}CO₂X¹ (wherein R^{f1} is a C₁₋₁₀ perfluoroalkylene group which may contain an etheric oxygen atom, and X¹ is a hydrogen atom or a C₁₋₃ alkyl group).

The unsaturated dicarboxylic acid anhydride may, for example, be itaconic anhydride (IAH), citraconic anhydride (CAH), 5-norbornen-2,3-dicarboxylic anhydride (NAH) or maleic anhydride.

The monomer containing a hydroxy group may, for example, be a vinyl ester, a vinyl ether or an allyl ether.

The monomer containing an epoxy group may, for example, be allyl glycidyl ether, 2-methyl allyl glycidyl ether, glycidyl acrylate or glycidyl methacrylate.

The monomer containing an isocyanate group may, for example, be 2-acryloyloxyethyl isocyanate, 2-methacryloyloxyethyl isocyanate, 2-(2-acryloyloxyethoxy)ethyl isocyanate or 2-(2-methacryloyloxyethoxy)ethyl isocyanate.

The units (1) preferably have at least a carbonyl group-containing group as the functional group (Q) in view of excellent adhesion to the conductor layer or the plating layer. Further, the units (1) are, in view of excellent thermal stability and adhesion to the conductor layer or the plating layer, at least one member selected from the group consisting of IAH units, CAH units and NAH units, particularly preferably NAH units.

The units other than the units (1) and the units (2) may, for example, be units derived from other monomer such as a perfluoro(alkyl vinyl ether) (PAVE), hexafluoropropylene (HFP), vinyl fluoride, vinylidene fluoride (VdF), trifluoroethylene or chlorotrifluoroethylene (CTFE).

PAVE may, for example, be CF₂═CFOCF₃, CF₂═CFOCF₂CF₃, CF₂═CFOCF₂CF₂CF₃ (PPVE), CF₂═CFOCF₂CF₂CF₂CF₃ or CF₂═CFO(CF₂)₈F, and is preferably PPVE.

Other units are preferably PAVE units, particularly preferably PPVE units.

As a preferred fluororesin (a1), a copolymer of TFE, PPVE and an unsaturated dicarboxylic anhydride is preferred, and specifically, a TFE/PPVE/NAH copolymer, a TFE/PPVE/IAH copolymer and a TFE/PPVE/CAH copolymer may, for example, be mentioned.

The fluororesin (a) may have the functional group (Q) as the main chain terminal group. The functional group (Q) introduced as the main chain terminal group is preferably an alkoxycarbonyl group, a carbonate group, a carboxy group, a fluoroformyl group, an acid anhydride residue or a hydroxy group. Such a functional group may be introduced by properly selecting a radical polymerization initiator, a chain transfer agent or the like.

The content of the functional groups (Q) in the fluororesin (a) is preferably from 10 to 60,000 groups, more preferably from 100 to 50,000 groups, further preferably from 100 to 10,000 groups, particularly preferably from 300 to 5,000 groups per 1×10⁶ carbon atoms in the main chain of the fluororesin (a). When the content of the functional groups (I) is within the above range, the adhesion strength at the interface between the layer (A) and the conductor layer or the layer (B) will be higher.

The content of the functional groups (Q) may be measured by e.g. nuclear magnetic resonance (NMR) analysis or infrared absorption spectrum analysis. For example, the proportion (mol %) of units having the functional groups (Q) based on all the units constituting the fluororesin (a) is determined by e.g. infrared absorption spectrum analysis as disclosed in e.g. JP-A-2007-314720, and the content of the functional groups (Q) can be calculated from the proportion.

The melting point of the fluororesin (a) is preferably at least 260° C., more preferably from 260 to 320° C., further preferably from 295 to 315° C., particularly preferably from 295 to 310° C. When the melting point of the fluororesin (a) is at least the above lower limit value, the layer (A) will be excellent in the heat resistance. When the melting point of the fluororesin (a) is at most the above upper limit value, the fluororesin (a) is excellent in the forming property.

The melting point of the fluororesin (a) may be adjusted e.g. by the type or the proportion of units constituting the fluororesin (a), the molecular weight of the fluororesin (a), etc.

The melt flow rate (MFR) of the fluororesin (a) at 372° C. under a load of 49 N is preferably from 0.1 to 1,000 g/10 min, more preferably from 0.5 to 100 g/min, further preferably from 1 to 30 g/10 min. When the melt flow rate is at most the above upper limit value, the solder heat resistance tends to improve. When the melt flow rate is at least the above lower limit value, the fluororesin (a) is excellent in the forming property.

The melt flow rate is an index to the molecular weight of the fluororesin (a), and a high melt flow rate indicates a low molecular weight and a low melt flow rate indicates a high molecular weight. The melt flow rate of the fluororesin (a) may be adjusted by conditions for producing the fluororesin (a). For example, by shortening the polymerization time at the time of polymerization, the melt flow rate of the resulting fluororesin (a) tends to be high. Further, by reducing the amount of the radical polymerization initiator used at the time of production, the melt flow rate of the resulting fluororesin (a) tends to be low.

The dielectric constant of the fluororesin (a) is preferably from 2.0 to 3.2, more preferably from 2.0 to 3.0. The lower the dielectric constant of the fluororesin (a), the more the dielectric constant of the layer (A) can be lowered.

The dielectric constant of the fluororesin (a) may be adjusted, for example, by the content of the units (2). The higher the content of the units (2), the lower the dielectric constant of the fluororesin (a) tends to be.

The number of the fluororesin (a) contained in the layer (A) may be one or more.

### <Other Component>

The layer (A) may contain, within a range not to impair the effects of the present invention, glass fibers which are not in the form of woven fabric or non-woven fabric, additives, etc. The additive is preferably an inorganic filler having a low dielectric constant and a low dielectric dissipation factor.

The inorganic filler may, for example, be silica, clay, talc, calcium carbonate, mica, diatomaceous earth, alumina, zinc oxide, titanium oxide, calcium oxide, magnesium oxide, iron oxide, tin oxide, antimony oxide, calcium hydroxide, magnesium hydroxide, aluminum hydroxide, basic magnesium carbonate, magnesium carbonate, zinc carbonate, barium carbonate, dawsonite, hydrotalcite, calcium sulfate, barium sulfate, calcium silicate, montmorillonite, bentonite, activated clay, sepiolite, Imogolite, sericite, glass fibers, glass beads, silica balloons, carbon black, carbon nanotubes, carbon nanohorns, graphite, carbon fibers, glass balloons, carbon balloons, wood flour or zinc borate.

The inorganic filler may be porous or non-porous. The inorganic filler is preferably porous in view of lower dielectric constant and a lower dielectric dissipation factor.

The inorganic filler may be used alone or in combination of two or more.

The proportion of the fluororesin (a) in the layer (A) is preferably at least 50 mass %, more preferably at least 80 mass % in view of excellent electrical characteristics. The upper limit of the proportion of the fluororesin (a) is not particularly limited, and may be 100 mass %.

### <Heat Resistant Resin Layer (B)>

The layer (B) is a layer containing a heat resistant resin (b) (excluding the fluororesin (a)). By the electrical insulator layer containing the layer (B), the linear expansion coefficient of the electrical insulator layer can be made low as compared with a case of only the layer (A).

The thickness of the layer (B) is preferably from 3 to 500 μm per layer, more preferably from 5 to 300 μm, further preferably from 6 to 200 μm. When the thickness of the layer (B) is at least the above lower limit value, excellent electrical insulating property will be obtained, and unexpected deformation such as warpage is likely to be to suppressed. When the thickness of the layer (B) is at most the above upper limit value, the entire wiring substrate can be made thin.

The ratio B/A of the total thickness of the layer (B) to the total thickness of the layer (A) in the electrical insulator layer is preferably from 10 to 0.1, more preferably from 5 to 0.2. When the ratio B/A is at least the above lower limit value, unexpected deformation such as warpage on the wiring substrate is likely to be suppressed. When the ratio B/A is at most the above upper limit value, the resulting wiring substrate tends to have excellent electrical characteristics.

The ratio B/A should be selected considering the linear expansion coefficients of the layer (A) and the layer (B) so that the linear expansion coefficient of the electrical insulator layer will be from 0 to 35 ppm/° C.

<Hear resistant resin (b)>

The heat resistant resin (b) may, for example, be polyimide (such as aromatic polyimide), polyarylate, polysulfone, polyarylsulfone (such as polyethersulfone), aromatic polyamide, aromatic polyether amide, polyphenylene sulfide, polyaryletherketone, polyamide-imide or liquid crystalline polyester.

The heat resistant resin (b) is preferably polyimide or liquid crystalline polyester, and in view of heat resistance, particularly preferably polyimide.

The polyimide may be a thermosetting polyimide or may be a thermoplastic polyimide. In the case of a thermosetting polyimide, the polyimide in the layer (B) is a cured product of the thermosetting polyimide.

The polyimide is preferably aromatic polyimide.

The aromatic polyimide is preferably a wholly aromatic polyimide produced by condensation polymerization of an aromatic polyvalent carboxylic dianhydride and an aromatic diamine.

A polyimide is usually obtained by reaction (polycondensation) of a polyvalent carboxylic dianhydride (or its derivative) and a diamine via a polyamic acid (polyimide precursor).

A polyimide, particularly an aromatic polyimide, is insoluble in a solvent or the like and is infusible due to its stiff main chain structure. Accordingly, first, a polyimide precursor (polyamic acid or polyamide acid) soluble in an organic solvent is prepared by a reaction of a polyvalent carboxylic dianhydride and a diamine, and processing is conducted by various methods at a stage of the polyamic acid. Then, the polyamic acid is dehydrated by heating or by a chemical method to be cyclized (imidized) to be formed into a polyimide.

As specific examples of the aromatic polyvalent carboxylic dianhydride and the aromatic diamine, ones disclosed in JP-A-2012-145676, paragraphs [0055] and [0057] may be mentioned. They may be used alone or in combination of two or more.

As the heat resistant resin (b), a liquid crystalline polyester is also preferred with a view to improving electrical characteristics. Particularly, with a view to improving the heat resistance, a liquid crystalline polyester having a melting point of at least 300° C., a dielectric constant of at most 3.2 and a dielectric dissipation factor of at most 0.005 is preferred. As the liquid crystalline polyester, a film made of a liquid crystalline polyester such as “VECSTAR (registered trademark)” manufactured by KURARAY, CO., LTD. or “BIAC” manufactured by W.L. Gore & Associates, Co., Ltd. may be used.

The heat resistant resin layer (B) may contain one or more heat resistant resins (b).

### <Other Component>

The layer (B) may contain, within a range not to impair the effects of the present invention, glass fibers which are not in the form of woven fabric or non-woven fabric, additives, etc. The additive is preferably an inorganic filler having a low dielectric constant and a low dielectric dissipation factor. The inorganic filler may be the same inorganic filler as mentioned for the layer (A).

The proportion of the heat resistant resin (b) in the layer (B) is preferably at least 50 mass %, more preferably at least 80 mass %, in view of excellent heat resistance of the layer (B) and with a view to suppressing unexpected deformation such as warpage. The upper limit of the proportion of the heat resistant resin (b) is not particularly limited, and may be 100 mass %.

### (Conductor Layer)

As the conductor layer, a metal foil having a low electrical resistance is preferred. The metal foil may be a foil made of a metal such as copper, silver, gold or aluminum. The metal may be used alone or in combination of two or more. In a case where two or more metals are used in combination, the metal foil is preferably a metal foil having metal plating applied thereto, particularly preferably a copper foil having gold plating to applied thereto.

The thickness of the conductor layer is preferably from 0.1 to 100 μm per layer, more preferably from 1 to 50 μm, particularly preferably from 1 to 40 μm.

The types of the metal material and the thicknesses of the respective conductor layers may be different.

With respect to the conductor layer, the surface on the electrical insulator layer side may be roughened, with a view to reducing the skin effect when transmitting signals in a high frequency band. On the surface opposite from the roughened surface of the conductor layer, an anti-corrosive oxide coating of e.g. chromate may be formed.

The conductor layer may have a wiring formed by pattern forming as the case requires. Further, the conductor layer may have a form other than a wiring.

### (Plating Layer)

The plating layer is not limited so long as conduction between the first conductor layer and the second conductor layer is secured through the plating layer. The plating layer may, for example, be a copper plating layer, a gold plating layer, a nickel plating layer, a chromium plating layer, a zinc plating layer or a tin plating layer, and is preferably a copper plating layer.

As the application of the wiring substrate of the present invention, preferred is an antenna comprising the wiring substrate of the present invention, wherein at least one of the first conductor layer and the second conductor layer is a conductor layer having an antenna pattern. As the antenna, antennas disclosed in WO2016/121397 may, for example, be mentioned. The application of the wiring substrate of the present invention is not limited to an antenna, and the wiring substrate may be used as a printed wiring board such as a sensor or a communication device used particularly in a high frequency circuit.

The wiring substrate is useful also as a substrate for electronic equipment such as radar, a network router, a backplane or a wireless infrastructure for which high frequency characteristics are required, or a substrate for various sensors or a substrate for engine management sensors for automobiles, and is particularly useful to an application for which a reduction in the transmission loss in a millimeter wave band is required.

The wiring substrate is useful also as a substrate for electronic equipment such as radar, a network router, a backplane or a wireless infrastructure for which high frequency characteristics are required, or a substrate for various sensors or a substrate for engine management sensors for automobiles, and is particularly useful to an application for which a reduction in the transmission loss in a millimeter wave band is required.

In the present invention, the total thickness of the wiring substrate to be produced is preferably from 10 to 1,500 μm, more preferably from 12 to 200 μm. When the total thickness of the wiring substrate is at least the above lower limit value, unexpected deformation such as warpage is likely to be suppressed. When the total thickness of the wiring substrate is at most the above upper limit value, such a wiring substrate is excellent in the flexibility and is applicable as a flexible circuit board.

The rate of change of the resistance of the wiring substrate after a thermal shock test of conducting 100 cycles each comprising leaving the wiring substrate in an environment of −65° C. for 30 minutes and then leaving it in an environment of 125° C. for 30 minutes, based on the resistance before the thermal shock test, is preferably within a range of ±10%, more preferably within a range of ±7%, further preferably within a range of ±5%. When the rate of change is within such a range, the wiring substrate has excellent heat resistance. The absolute value of the rate of change tends to be small by using a fluororesin (a) having a high melting point, a thermoplastic heat resistant resin (b) having a high melting point or a heat resistant resin (b) which is a cured product of a thermosetting resin.

### [Process for Producing Wiring Substrate]

The process for producing a wiring substrate of the present invention is roughly classified into the following process (i) and process (ii) depending upon whether a laminate on which hole processing is to be conducted has the first conductor layer or not.

Process (i): A process of conducting hole processing on a laminate having a first conductor layer.

Process (ii): A process of conducting hole processing on a laminate having no first conductor layer.

Now, the process (i) and the process (ii) will be respectively described.

### (Process (i))

The process (i) has the following steps.

(i-1): A step of forming, in a laminate having a layer structure of first conductor layer/electrical insulator layer/second conductor layer, a hole which opens at least from the first conductor layer through the second conductor layer.

(i-2): A step of applying, to an inner wall surface of the hole formed in the laminate, one or both of a treatment with a permanganic acid solution and a plasma treatment without conducting an etching treatment using metal sodium.

(i-3): A step of forming a plating layer on the inner wall surface of the hole after the step (i-2).

<Step (i-1)>

The method for producing the laminate is not particularly limited and a known method may be employed.

For example, a laminate having a layer structure of first conductor layer/layer (A)/layer (B)/layer (A)/second conductor layer may be obtained by the following method. A metal foil, a resin film made of the fluororesin (a), a resin film made of the heat resistant resin (b), a resin film made of the fluororesin (a) and a metal foil are laminated in this order and heat-pressed.

The hole is formed so that it opens at least from the first conductor layer through the second conductor layer. That is, the hole is formed so that it penetrates at least the electrical insulator layer positioned between the first conductor layer and the second conductor layer. In a case where the hole is formed from the first conductor layer side of the electrical insulator layer, so long as the first conductor layer and the second conductor layer are connected by the hole, the hole may or may not reach the interior of the second conductor layer. In a case where the hole is formed from the second conductor layer side of the electrical insulator layer, so long as the first conductor layer and the second conductor layer are connected by the hole, the hole may or may not reach the interior of the first conductor layer.

The method of forming the hole in the laminate is not particularly limited, and a known method may be employed, such as a method of forming a hole by a drill or a laser.

The diameter of the hole formed in the laminate is not particularly limited and may properly be determined.

<Step (i-2)>

After the hole is formed in the laminate and before a plating layer is formed on the inner wall surface of the hole, as a pre-treatment, either one or both of a treatment with a permanganic acid solution and a plasma treatment is applied to the inner wall surface of the hole. In the step (i-2), an etching treatment using metal sodium is not conducted as the pre-treatment.

In a case where both of the treatment with a permanganic acid solution and a plasma treatment are conducted as the pre-treatment, it is preferred to conduct the treatment with a permanganic acid solution first in view of removability of smear (resin residue) which forms at the time of forming the hole, and in that the adhesion between the inner wall surface of the hole and the plating layer will sufficiently be secured and the plating layer will readily be formed on the entire inner wall surface of the hole. However, the treatment with a permanganic acid solution may be conducted after the plasma treatment.

<Step (i-3)>

The method of forming the plating layer on the inner wall surface of the hole after the pre-treatment is not particularly limited and for example, electroless plating may be mentioned.

In the present invention, by the electrical insulator layer having a layer containing a fluororesin (a) having functional groups (Q) and having excellent adhesion to a plating layer and containing no reinforcing fiber substrate made of woven fabric or non-woven fabric, the plating layer is formed on the entire inner wall surface of the hole without conducting an etching treatment using metal sodium, whereby conduction between the first conductor layer and the second conductor layer is stably secured.

Further, in the present invention, by the electrical insulator layer having the layer (B) in addition to the layer (A) and having a linear expansion coefficient controlled to be from 0 to 35 ppm/° C., unexpected deformation such as warpage on the obtained wiring substrate can be suppressed.

Now, an example of the process (i) will be described.

### First Embodiment

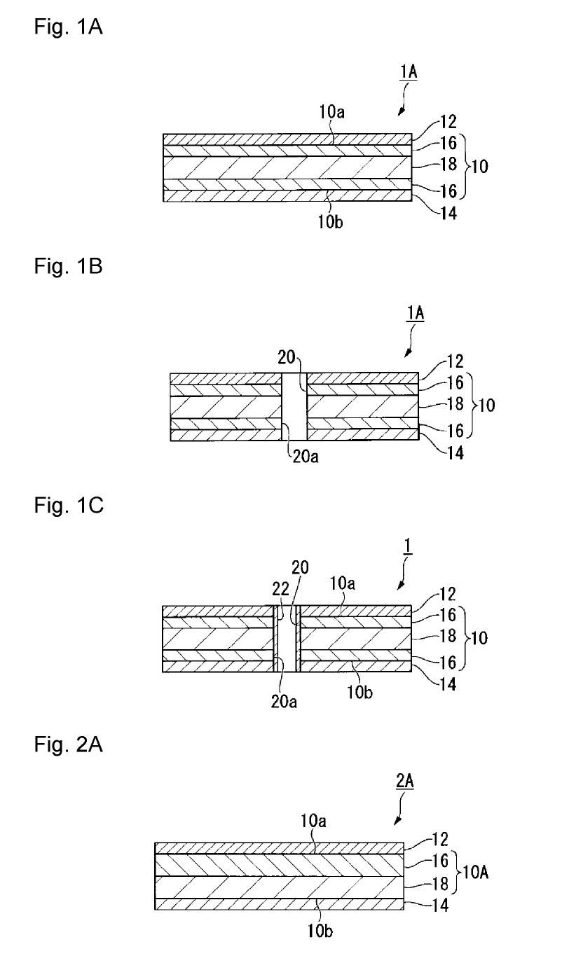

In a case where the wiring substrate 1 is produced by the process (i), a laminate 1A having a layer structure of first conductor layer 12/electrical insulator layer 10/second conductor layer 14 as shown in FIG. 1A is used. The electrical insulator layer 10 has a layer structure of layer (A) 16/layer (B) 18/layer (A) 16. As shown in FIG. 1B, a hole 20 which penetrates from the first conductor layer 12 through the second conductor layer 14 is formed in the laminate 1A e.g. by a drill or laser. Then, either one or both of a treatment with a permanganic acid solution and a plasma treatment is applied to an inner wall surface 20a of the hole 20 formed without conducting an etching treatment using metal sodium, and then as shown in FIG. 10, a plating layer 22 is formed by applying e.g. electroless plating on the inner wall surface 20a of the hole 20.

### Second Embodiment

In a case where a wiring substrate 2 is produced by the process (i), a laminate 2A having a layer structure of first conductor layer 12/electrical insulator layer 10A/second conductor layer 14, as shown in FIG. 2A, is used. The electrical insulator layer 10A has a layer structure of layer (A) 16/layer (B) 18. In the same manner as in the case of the wiring substrate 1, as shown in FIG. 2B, a hole 20 which penetrates from the first conductor layer 12 through the second conductor layer 14 is formed in the laminate 2A. Then, either one or both of a treatment with a permanganic acid solution and a plasma treatment is applied to an inner wall surface 20a of the hole 20 formed without conducting an etching treatment using metal sodium, and then as shown in FIG. 2C, a plating layer 22 is formed on the inner wall surface 20a of the hole 20.

### Third Embodiment

In a case where a wiring substrate 3 is produced by the process (i), a laminate 3A having a layer structure of first conductor layer 12/electrical insulator layer 10B/second conductor layer 14, as shown in FIG. 3A, is used. The electrical insulator layer 10B has a layer structure of layer (B) 18/layer (A) 16/layer (B) 18. In the same manner as in the case of the wiring substrate 1, as shown in FIG. 3B, a hole 20 which penetrates from the first conductor layer 12 through the second conductor layer 14 is formed in the laminate 3A. Then, either one or both of a treatment with a permanganic acid solution and a plasma treatment is applied to an inner wall surface 20a of the hole 20 formed without conducting an etching treatment using metal sodium, and then as shown in FIG. 3C, a plating layer 22 is formed by applying e.g. electroless plating on the inner wall surface 20a of the hole 20.

(Process (ii))

The process (ii) has the following steps.

(ii-1): A step of forming, in a laminate having a layer structure of electrical insulator layer/second conductor layer, a hole which opens at least from a first surface of the electrical insulator layer through the second conductor layer.

(ii-2): A step of applying, to an inner wall surface of the hole formed in the laminate, either one or both of a treatment with a permanganic acid solution and a plasma treatment without conducting an etching treatment using metal sodium.

(ii-3): A step of forming a plating layer on the inner wall surface of the hole after the step (ii-2).

(ii-4): A step of forming the first conductor layer on the first surface of the electrical insulator layer.

<Step (ii-1)>

The step (ii-1) may be carried out in the same manner as the step (i-1) using the same laminate as in the process (i) except that it has no first conductor layer, except that a hole which opens at least from the first surface of the electrical insulator layer through the second conductor layer is formed.

<Step (ii-2), step (ii-3)>

The step (ii-2) and the step (ii-3) may be carried out in the same manner as the step (i-2) and the step (i-3) except that the laminate having the hole formed in the step (ii-1) is used.

<Step (ii-4)>

The method of forming the first conductor layer on the first surface of the electrical insulator layer is not particularly limited and for example, electroless plating may be mentioned. Further, as the case requires, a pattern may be formed on the first conductor layer by etching.

The step (ii-4) may be carried out before the step (ii-3), may be carried out after the step (ii-3), or may be carried out simultaneously with the step (ii-3).

Now, an example of the process (ii) will be described.

### Fourth Embodiment

In a case where a wiring substrate 1 is produced by the process (ii), for example, the following process may be mentioned.

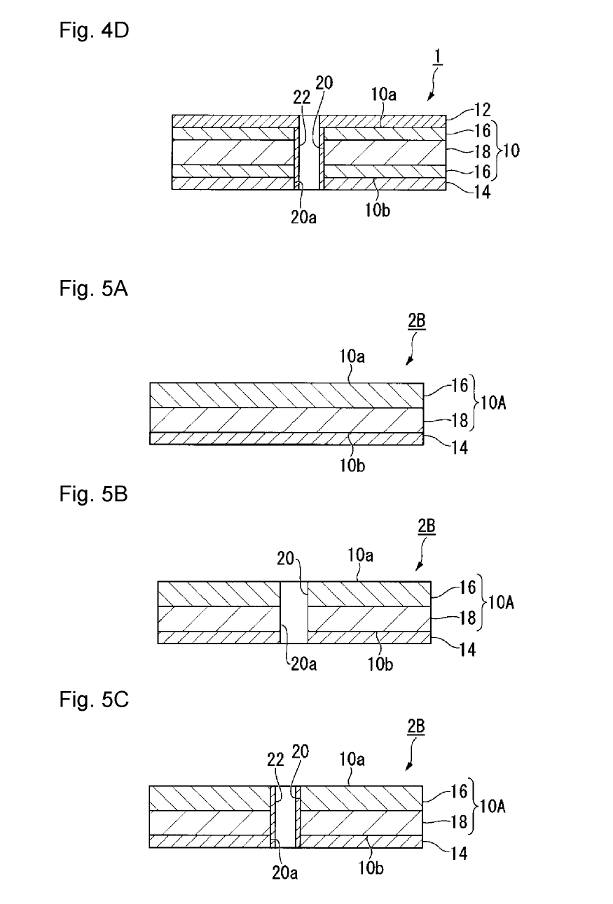

A laminate 1B having a layer structure of electrical insulator layer 10/second conductor layer 14 having a second conductor layer 14 on a second surface 10b of an electrical insulator layer 10, as shown in FIG. 4A, is used. The electrical insulating layer 10 has a layer structure of layer (A) 16/layer (B) 18/layer (A) 16. As shown in FIG. 4B, a hole 20 which penetrates from the electrical insulator layer 10 through the second conductor layer 14 is formed in the laminate 1B e.g. by a drill or laser. Then, either one or both of a treatment with a permanganic acid solution and a plasma treatment is applied to an inner wall surface 20a of the hole 20 formed without conducting an etching treatment using metal sodium. Then, as shown in FIG. 4C, a plating layer 22 is formed by applying e.g. electroless plating on the inner wall surface 20a of the hole 20. Then, as shown in FIG. 4D, a first conductor layer 12 is formed by applying e.g. electroless plating on the first surface 10a of the electrical insulator layer 10.

### Fifth Embodiment

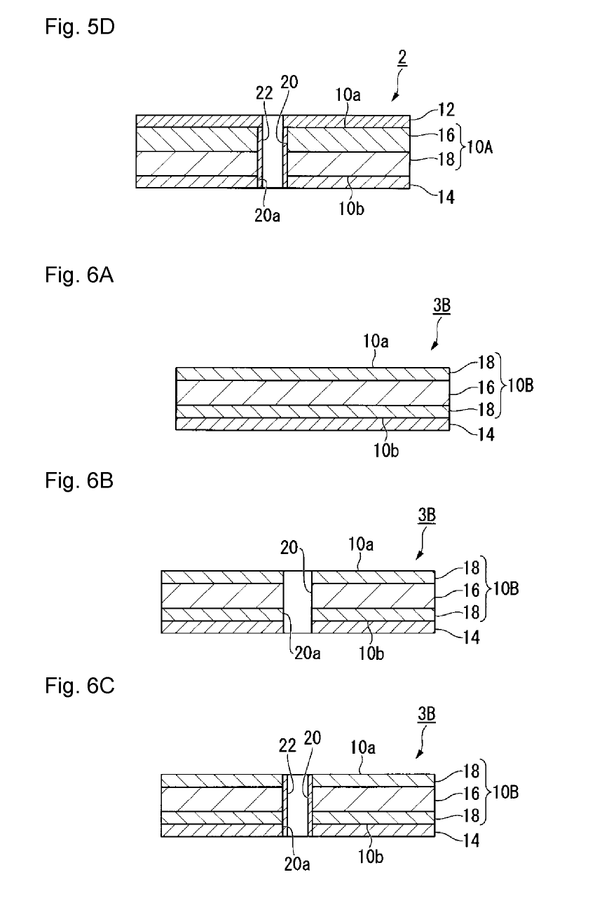

In a case where a wiring substrate 2 is produced by the process (ii), a laminate 2B having a layer structure of electrical insulator layer 10A/second conductor layer 14, having a second conductor layer 14 on a second surface 10b of an electrical insulator layer 10A as shown in FIG. 5A is used. The electrical insulator layer 10A has a layer structure of layer (A) 16/layer (B) 18. In the same manner as in the case of the wiring substrate 1, as shown in FIG. 5B, a hole 20 which penetrates from the electrical insulator layer 10A through the second conductor layer 14 is formed in the laminate 2B. And, either one or both of a treatment with a permanganic acid solution and a plasma treatment is applied to an inner wall surface 20a of the hole 20 formed without conducting an etching treatment using metal sodium. Then, as shown in FIG. 5C, a plating layer 22 is formed on the inner wall surface 20a of the hole 20, and as shown in FIG. 5D, a first conductor layer 12 is formed on a first surface 10a of the electrical insulator layer 10.

### Sixth Embodiment

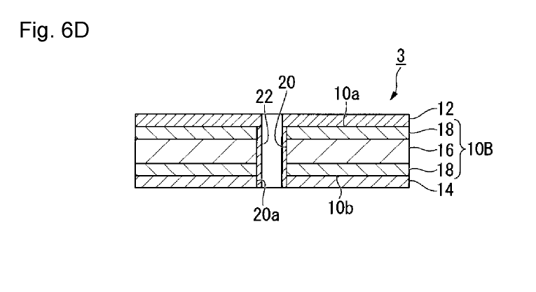

In a case where a wiring substrate 3 is produced by the process (ii), a laminate 3B having a layer structure of electrical insulator layer 10B/second conductor layer 14, having a second conductor layer 14 on a second surface 10b of an electrical insulator layer 10B, as shown in FIG. 6A is used. The electrical insulator layer 10B has a layer structure of layer (B) 18/layer (A) 16/layer (B) 18. In the same manner as in the case of the wiring substrate 1, as shown in FIG. 6B, a hole 20 which penetrates from the electrical insulator layer 10B through the second conductor layer 14 is formed in the laminate 3B. And, either one or both of a treatment with a permanganic acid solution and a plasma treatment is applied to an inner wall surface 20a of the hole 20 without conducting an etching treatment using metal sodium. Then, as shown in FIG. 6C, a plating layer 22 is formed on the inner wall surface 20a of the hole 20, and as shown in FIG. 6D, a first conductor layer 12 is formed on a first surface 10a of the electrical insulator layer 10.

As described above, in the process for producing a wiring substrate of the present invention, the electrical insulator layer contains a layer (A) containing a fluororesin (a) having functional groups (Q) and being excellent in adhesion, and contains no reinforcing fiber substrate made of woven fabric or non-woven fabric. Thus, adhesion between the inner wall surface of the hole and the plating layer is sufficiently secured even without conducting an etching treatment using metal sodium to the hole formed in the electrical insulator layer. Accordingly, the plating layer is formed on the entire inner wall surface of the hole, and conduction failure in the hole can be suppressed. The etching treatment using metal sodium being unnecessary, is advantageous also in that existing equipment for producing a wiring substrate using a resin containing no fluorine atom as an insulating material may be utilized as it is.

Further, in the process for producing a wiring substrate of the present invention, the electrical insulator layer contains the layer (B) in addition to the layer (A) and has a linear expansion coefficient controlled to be from 0 to 35 ppm/° C. Accordingly, in the obtainable wiring substrate, the linear expansion coefficients of the first conductor layer and the second conductor layer are close to the linear expansion coefficient of the electrical insulator layer, and unexpected deformation such as warpage is suppressed.

### EXAMPLES

Now, the present invention will be described in further detail with reference to Examples. However, it should be understood that the present invention is by no means restricted thereto.

### [Copolymer Composition]

In the copolymer composition of the fluororesin, the proportion (mol %) of NAH units was determined by the following infrared absorption spectrum analysis. The proportions of other units were determined by molten NMR analysis and fluorine content analysis.

### (Measurement of Proportion of NAH Units)

The fluororesin was press-formed to obtain a 200 μm film, which was subjected to infrared absorption spectrum analysis. In the obtained infrared absorption spectrum, the absorbance of an absorption peak at 1,778 cm⁻¹ which is an absorption peak of

NAH units was measured. The absorbance was divided by the NAH molar absorption coefficient 20,810 mol⁻¹·I·cm⁻¹ to determine the proportion of NAH units in the fluororesin.

### [Melting Point]

Using a differential scanning calorimeter (DSC apparatus) manufactured by Seiko Instruments & Electronics Ltd., the melting peak when the fluororesin was heated at a rate of 10° C./min was recorded, and the temperature (° C.) corresponding to the maximum value of the melting peak was taken as the melting point (Tm).

### [MFR]

Using a melt indexer manufactured by TECHNO SEVEN, the mass (g) of the fluororesin which flowed from a nozzle having a diameter of 2 mm and a length of 8 mm in 10 minutes (unit time) at 372° C. under a load of 49 N was measured and taken as MFR (g/10 min).

### [Measurement of Dielectric Constant of Fluororesin]

Using a dielectric breakdown test apparatus (YSY-243-100RHO (manufactured by YAMAYOSHIKENKI.COM)), by transformer bridge method in accordance with ASTM D150, the dielectric constant of the fluororesin was measured at a frequency of 1 MHz in a test environment at a temperature of 23° C.±2° C. under a relative humidity of 50%±5% RH.

### [Measurement of Dielectric Constant of Electrical Insulator Layer]

The copper foil of the laminate was removed by etching, and with respect to the exposed electrical insulator layer, by split post dielectric resonator method (SPDR method), the dielectric constant at a frequency of 2.5 GHz was obtained in an environment at 23° C.±2° C. under 50%±5% RH.

As equipment in measurement of the dielectric constant, split post dielectric resonator of nominal fundamental frequency 2.5 GHz type manufactured by QWED, vector network analyzer E8361C manufactured by Keysight Technologies and 85071E option 300 dielectric constant calculation software manufactured by Keysight Technologies were used.

### [Measurement of Linear Expansion Coefficient]

The copper foil of the laminate is removed by etching, and the exposed electrical insulator layer is cut into a strip of 4 mm×55 mm to prepare a sample. The sample is dried in an oven at 250° C. for 2 hours for conditioning. Then, the sample is heated from 30° C. to 250° C. at a rate of 5° C./min using a thermal mechanical analyzer (TMA/SS6100) manufactured by Seiko Instruments Inc., in an air atmosphere at a distance between chucks of 20 mm while applying a load of 2.5 g, and the amount of displacement accompanying the linear expansion of the sample is measured. After completion of measurement, the linear expansion coefficient (ppm/° C.) from 50 to 100° C. is determined from the amount of displacement of the sample from 50 to 100° C.

### [Evaluation of Plating Layer]

With respect to the wiring substrate obtained in each Ex., the outer appearance of the plating layer formed on the inner wall surface of the hole was observed, and evaluation was made based on the following standards.

◯ (Excellent): The plating layer formed on the entire inner wall surface of the hole.

x (Failure): The plating layer formed partially on the inner wall surface of the hole, and a part of the inner wall surface of the hole exposed.

### [Evaluation of Heat Resistance]

With respect to the wiring substrate, the resistances between copper foils on both sides of the electrical insulator layer via the plating layer formed on the inner wall surface of the hole, before and after the following thermal shock test were measured. To measure the resistance, mΩ HiTESTER (model: 3540, manufactured by HIOKI EE. CORPORATION) was used.

As the thermal shock test, 100 cycles each comprising leaving the wiring substrate in an environment of −65° C. for 30 minutes and then leaving it in an environment of 125° C. for 30 minutes, were conducted.

A wiring substrate with a change of the resistance as between before and after the thermal shock test being within a range of ±10%, was rated as being acceptable.

### [Materials Used]

NAH: 5-norbornene-2,3-dicarboxylic anhydride (himic anhydride, manufactured by Hitachi Chemical Company, Ltd.)

AK225cb: 1,3-dichloro-1,1,2,2,3-pentafluoropropane (AK225cb, manufactured by Asahi Glass Company, Limited)

PPVE: CF₂═CFO(CF₂)₃F (manufactured by Asahi Glass Company, Limited)

### Production Example 1

369 kg of AK225cb and 30 kg of PPVE were charged into a polymerization vessel equipped with a stirring machine having an internal capacity of 430 L (liter) which had been deaerated. Then, the interior of the polymerization vessel was heated to 50° C., 50 kg of TFE was charged, and the pressure in the polymerization vessel was elevated to 0.89 MPa/G. “/G” means that the pressure is the gage pressure.

(Perfluorobutyryl) peroxide and PPVE were dissolved in AK225cb at concentrations of 0.36 mass % and 2 mass %, respectively, to prepare a polymerization initiator solution. Polymerization was conducted while 3 L of the polymerization initiator solution was continuously added to the polymerization vessel at a rate of 6.25 mL per minute. During the polymerization reaction, TFE was continuously charged so that the pressure in the polymerization vessel was kept at 0.89 MPa/G. Further, a solution having NAH dissolved in AK225cb at a concentration of 0.3 mass % was continuously charged at a rate of 0.1 mol % based on the number of moles of TFE charged during the polymerization reaction.

8 hours after initiation of the polymerization, at a point when 32 kg of TFE was charged, the temperature in the polymerization vessel was decreased to room temperature, and the pressure was purged to normal pressure. The obtained slurry was subjected to solid-liquid separation from AK225cb, followed by drying at 150° C. for 15 hours to obtain 33 kg of a granular fluororesin (a1-1).

The copolymer composition of the fluororesin (a1-1) was NAH units/TFE units/PPVE units=0.1/97.9/2.0 (mol %). The melting point of the fluororesin (a1-1) was 300° C., the dielectric constant was 2.1, and MFR was 17.6 g/10 min. Further, the content of the functional groups (Q) (acid anhydride groups) in the fluororesin (a1-1) was 1,000 groups per 1×10⁶ carbon atoms in the main chain of the fluororesin (a1-1).

### Production Example 2

Using a single screw extruder of 30 mm in diameter having a coat hanger die with a width of 750 mm, the fluororesin (a1-1) was extruded at a die temperature of 340° C. to obtain a fluororesin film (hereinafter referred to as “film (1)”) having a thickness of 12.5 μm. An electrolytic copper foil having a thickness of 12 μm (manufactured by Fukuda Metal Foil & Powder Co., Ltd., CF-T4X-SVR-12, surface roughness (Rz): 1.2 μm), the film (1) and a polyimide film having a thickness of 25 μm (manufactured by DU PONT-TORAY CO., LTD., tradename “Kapton (registered trademark)”) which is a heat resistant resin (b) film were laminated in the order of copper foil/film (1)/polyimide film/film (1)/copper foil and vacuum-pressed at a temperature of 360° C. under a pressure of 3.7 MPa for 10 minutes to prepare laminate (α-1). In the laminate (α-1), by the portion of film (1)/polyimide film/film (1) being pressed, an electrical insulator layer having a three layer structure of fluororesin layer (A-1)/heat resistant resin layer (B-1)/fluororesin layer (A-1) was formed.

The copper foils on both surfaces of the laminate (α-1) were removed by etching, and the dielectric constant and the linear expansion coefficient of the electrical insulator layer were measured, whereupon the dielectric constant was 2.86, and the linear expansion coefficient was 19 ppm/° C.

### [Production Example 3]

Using a single screw extruder of 30 mm in diameter having a coat hanger die with a width of 750 mm, the fluororesin (a1-1) was extruded at a die temperature of 340° C. to obtain a fluororesin film (hereinafter referred to as “film (2)”) having a thickness of 50 μm. An electrolytic copper foil having a thickness of 12 μm (manufactured by Fukuda Metal Foil & Powder Co., Ltd., CF-T4X-SVR-12, surface roughness (Rz): 1.2 μm) and the film (2) were laminated in the order of copper foil/film (2)/copper foil and vacuum-pressed at a temperature of 360° C. under a pressure of 3.7 MPa for 10 minutes to prepare a laminate (α-2). In the laminate (α-2), by the portion of film (2) being pressed, an electrical insulator layer having a single layer structure consisting of a fluororesin layer (A-2) was formed.

The copper foils on both surfaces of the laminate (α-2) were removed by etching, and the dielectric constant and the linear expansion coefficient of the electrical insulator layer were measured, whereupon the dielectric constant was 2.07, and the linear expansion coefficient was 198 ppm/° C.

### Production Example 4

From a double-sided copper-clad laminate (manufactured by New Nippon Steel Chemical Co., Ltd., ESPANEX M series (MB12-50-12REQ)) having a polyimide resin layer with a thickness of 50 μm as an insulating layer and having copper foils with a thickness of 12 μm formed on both surfaces, the copper foil on one surface was removed by etching to prepare a single-sided copper-clad laminate. The surface from which the copper foil was removed by etching of the single-sided copper-clad laminate, and the film (2) were bonded and laminated in the order of single-sided copper-clad laminate/film (2)/film (2)/single-sided copper-clad laminate and vacuum-pressed at a temperature of 360° C. under a pressure of 3.7 MPa for 10 minutes to prepare a laminate (a-3). In the laminate (α-3), by the portion of polyimide resin layer/film (2)/film (2)/polyimide resin layer being pressed, an electrical insulator layer having a three layer structure of heat resistant resin layer (B-2)/fluororesin layer (A-3)/heat resistant resin layer (B-2) was formed.

The copper foils on both surfaces of the laminate (α-3) were removed by etching, and the dielectric constant and the linear expansion coefficient of the electrical insulator layer were measured, whereupon the dielectric constant was 2.88, and the linear expansion coefficient was 28 ppm/° C.

### Example 1

On the laminate (α-1), hole processing of 0.3 mm in diameter was conducted by a drill to form a hole (through-hole) which penetrated from one surface to the other surface of the laminate (α-1). Then, a desmear treatment (treatment with a permanganic acid solution) was applied to the inner wall surface of the hole formed. The laminate (α-1) having the through-hole formed therein was treated with a swelling liquid (a mixed liquid of MLB211 and CupZ in a mixing ratio of 2:1 by mass manufactured by RHOM and HAAS) at a liquid temperature of 80° C. for a treatment time of 5 minutes, treated with an oxidizing liquid (a mixed liquid of MLB213A-1 and MLB213B-1 in a mixing ratio of 1:1.5 by mass manufactured by RHOM and HAAS) at a liquid temperature of 80° C. for a treatment time of 6 minutes and treated with a neutralizer (MLB216-2 manufactured by RHOM and HAAS) at a liquid temperature of 45° C. for a treatment time of 5 minutes.

In order to form a plating layer on the inner wall surface of the through-hole in the laminate (α-1) after the desmear treatment, a plating treatment was applied to the inner wall surface of the through-hole in the laminate (α-1). With respect to the plating treatment, a system solution is commercially available from RHOM and HAAS, and electroless plating was conducted using the system solution in accordance with the published procedure. The laminate (α-1) after the desmear treatment was treated with a cleaning fluid (ACL-009) at a liquid temperature of 55° C. for a treatment time of 5 minutes. After washing with water, the laminate (α-1) was subjected to a soft etching treatment with a sodium persulfate/sulfuric acid soft etching agent at a liquid temperature of room temperature for a treatment time of 2 minutes. After washing with water, the laminate (α-1) was subjected to an activation treatment with a treatment liquid (a mixed liquid of MAT-2-A and MAT-2-B in a volume ratio of 5:1) at a liquid temperature of 60° C. for a treatment time of 5 minutes. The laminate (α-1) was subjected to a reduction treatment with a treatment liquid (a mixed liquid of MAB-4-A and MAB-4-B in a volume ratio of 1:10) at a liquid temperature of 30° C. for a treatment time of 3 minutes so that a Pd catalyst to precipitate copper in electroless plating was deposited on the inner wall surface of the through-hole. After washing with water, the laminate (α-1) was subjected to a plating treatment with a treatment liquid (PEA-6) at a liquid temperature of 34° C. for a treatment time of 30 minutes to precipitate copper on the inner wall surface of the through-hole to form a plating layer thereby to obtain a wiring substrate.

### Example 2

On the laminate (α-1), hole processing of 0.3 mm in diameter was conducted by a drill to form a hole (through-hole) which penetrated from one surface to the other surface of the laminate (α-1). Then, to the inner wall surface of the hole formed, a treatment with a permanganic acid solution using a desmear liquid containing permanganic acid sodium salt was applied in the same manner as in Example 1 and then a plasma treatment was applied in an argon gas atmosphere. Then, on the inner wall surface of the hole, a plating layer comprising copper was formed by electroless plating to obtain a wiring substrate.

### Example 3

On the laminate (α-1), instead of hole processing by a drill, through-hole processing was conducted by using a CO₂ laser (manufactured by Hitachi Ltd., LC-2K212) with a diameter set at 0.15 mm, at an output of 24.0 W at a frequency of 2,000 Hz, whereby a through-hole of 0.15 mm in diameter was formed. A wiring substrate was obtained in the same manner as in Example 1 except that the hole of 0.15 mm in diameter was formed.

### Example 4

On the laminate (α-1), instead of hole processing by a drill, through-hole processing was conducted by using a CO₂ laser (manufactured by Hitachi Ltd., LC-2K212) with a diameter set at 0.1 mm, at an output of 24.0 W at a frequency of 2,000 Hz, whereby a through-hole of 0.15 mm in diameter was formed. A wiring substrate was obtained in the same manner as in Example 2 except that the hole of 0.15 mm in diameter was formed.

### Example 5

On the laminate (α-3), hole processing of 0.3 mm in diameter was conducted by a drill to form a hole (through-hole) which penetrated from one surface to the other surface of the laminate (α-3). Then, to the inner wall surface of the hole formed, a treatment with a permanganic acid solution using a desmear liquid containing permanganic acid sodium salt was applied, and then a plasma treatment was applied in an argon gas atmosphere. Then, on the inner wall surface of the hole, a plating layer comprising copper was formed by electroless plating to obtain a wiring substrate.

### Example 6

On the laminate (α-1), hole processing of 0.3 mm in diameter was conducted by a drill to form a hole (through-hole) which penetrated from one surface to the other surface of the laminate (α-1). Then, to the inner wall surface of the hole formed, a treatment with a permanganic acid solution was applied in the same manner as in Example 1 except that an ultrasonic wave treatment at 28 kHz was conducted in each of the treatment steps with the respective liquids, and then, a plating layer comprising copper was formed on the inner wall surface of the hole by electroless plating to obtain a wiring substrate.

### Comparative Example 1

A wiring substrate was obtained in the same manner as in Example 1 except that the laminate (α-2) was used instead of the laminate (α-1).

The layer structure, the dielectric constant and the linear expansion coefficient of the electrical insulator layer, the diameter of the hole, the type of the pre-treatment and evaluation results in each Ex. are shown in Table 1.

TABLE 1

| | | | | | Pre-treatment of hole | | | Heat resistance | | |
|---|---|---|---|---|---|---|---|---|---|---|
| | Insulator layer | | | | Treatment | | | Resistance | Resistance | |
| | | | Linear | | with | | Evaluation | before | after | Change |
| | | | expansion | Diameter | permanganic | | of | thermal | thermal | of |
| | Layer | Dielectric | coefficient | of hole | acid | Plasma | plating | shock | shock | resistance |
| | structure | constant | [ppm/° C.] | [mm] | solution | treatment | layer | [Ω] | [Ω] | [%] |
| Example | A-1 (12.5 μm)/ | 2.86 | 19 | 0.3 | Conducted | Nil | ○ | | | |
| 1 | B-1 (25 μm)/ | | | | | | | | | |
| | A-1 (12.5 μm) | | | | | | | | | |
| Example | A-1 (12.5 μm)/ | 2.86 | 19 | 0.3 | Conducted | Conducted | ○ | | | |
| 2 | B-1 (25 μm)/ | | | | | | | | | |
| | A-1 (12.5 μm) | | | | | | | | | |
| Example | A-1 (12.5 μm)/ | 2.86 | 19 | 0.1 | Conducted | Nil | ○ | 8.23 | 8.28 | 0.61 |
| 3 | B-1 (25 μm)/ | | | | | | | | | |
| | A-1 (12.5 μm) | | | | | | | | | |
| Example | A-1 (12.5 μm)/ | 2.86 | 19 | 0.1 | Conducted | Conducted | ○ | 7.91 | 7.66 | −3.2 |
| 4 | B-1 (25 μm)/ | | | | | | | | | |
| | A-1 (12.5 μm) | | | | | | | | | |
| Example | B-2 (50 μm)/ | 2.88 | 28 | 0.3 | Conducted | Conducted | ○ | | | |
| 5 | A-3 (100 μm)/ | | | | | | | | | |
| | B-2 (50 μm) | | | | | | | | | |
| Example | A-1 (12.5 μm)/ | 2.86 | 19 | 0.3 | Conducted | Nil | ○ | | | |
| 6 | B-1 (25 μm)/ | | | | | | | | | |
| | A-1 (12.5 μm) | | | | | | | | | |
| Comp. | A-2 (50 μm) | 2.07 | 198 | 0.3 | Conducted | Nil | ○ | | | |
| Example | | | | | | | | | | |
| 1 | | | | | | | | | | |

As shown in Table 1, in the wiring substrates in Examples 1 to 5 produced by the production process of the present invention, the plating layer was formed on the entire inner wall surface of the hole even without conducting an etching treatment using metal sodium. Further, the firing substrates in Examples 1 to 5 will not have warpage since the electrical insulator layer has a linear expansion coefficient of from 0 to 35 ppm/° C. Further, the wiring substrates in Examples 3 and 4 were also excellent in the heat resistance since the change of the resistance as between before and after the thermal shock test was within a range of ±10%.

Whereas, in the wiring substrate in Comparative Example 1, although the plating layer was formed on the entire inner wall surface of the hole, the electrical insulator layer had a linear expansion coefficient of so high as 198 ppm/° C., and the wiring substrate is likely to have warpage, such being practically problematic.

This application is a continuation of PCT Application No. PCT/JP2016/081171, filed on Oct. 20, 2016, which is based upon and claims the benefit of priority from Japanese Patent Application No. 2015-208154 filed on Oct. 22, 2015. The contents of those applications are incorporated herein by reference in their entireties.

### REFERENCE SYMBOLS

1 to 3: Wiring substrate, 1A to 3A, 1B to 3B: laminate, 10, 10A, 10B: electrical insulator layer, 10a: first surface, 10b: second surface, 12: first conductor layer, 14: second conductor layer, 16: fluororesin layer (A), 18: heat resistant resin layer (B), 20: hole, 20a: inner wall surface, 22: plating layer.

What is claimed is:

1. A process for producing a wiring substrate comprising an electrical insulator layer, a first conductor layer formed on a first surface of the electrical insulator layer and a second conductor layer formed on a second surface opposite from the first surface of the electrical insulator layer, and having a hole which opens at least from the first conductor layer through the second conductor layer and having a plating layer formed on an inner wall surface of the hole; wherein
the electrical insulator layer has a multi-layered structure containing at least one fluororesin layer (A) containing a melt-moldable fluororesin (a) having at least one type to of functional groups selected from the group consisting of carbonyl group-containing groups, hydroxy groups, epoxy groups and isocyanate groups, and at least one heat resistant resin layer (B) containing a heat resistant resin (b) (excluding the fluororesin (a)), contains no reinforcing fiber substrate made of woven fabric or non-woven fabric, and has a dielectric constant of from 2.0 to 3.5 and a linear expansion coefficient of from 0 to 35 ppm/° C.;
the process comprising forming the hole in a laminate comprising the first conductor layer, the electrical insulator layer and the second conductor layer; and
applying, to the inner wall surface of the hole formed, either one or both of a treatment with a permanganic acid solution and a plasma treatment without conducting an etching treatment using metal sodium, and then forming the plating layer on the inner wall surface of the hole.

2. A process for producing a wiring substrate comprising an electrical insulator layer, a first conductor layer formed on a first surface of the electrical insulator layer and a second conductor layer formed on a second surface opposite from the first surface of the electrical insulator layer, and having a hole which opens at least from the first conductor layer through the second conductor layer and a plating layer formed on an inner wall surface of the hole; wherein
the electrical insulator layer has a multi-layered structure containing at least one fluororesin layer (A) containing a melt-moldable fluororesin (a) having at least one type of functional groups selected from the group consisting of carbonyl group-containing groups, hydroxy groups, epoxy groups and isocyanate groups, and at least one heat resistant resin layer (B) containing a heat resistant resin (b) (excluding the fluororesin (a)), contains no reinforcing fiber substrate made of woven fabric or non-woven fabric, and has a dielectric constant of from 2.0 to 3.5 and a linear expansion coefficient of from 0 to 35 ppm/° C.;
the process comprising forming the hole in a laminate comprising the electrical insulator layer and the second conductor layer;
applying, to the inner wall surface of the hole formed, either one or both of a treatment with a permanganic acid solution and a plasma treatment without conducting an etching treatment using metal sodium, then forming the plating layer on the inner wall surface of the hole, and forming the first conductor layer on the first surface of the to electrical insulator layer.

3. The process for producing a wiring substrate according to claim 1, wherein the electrical insulator layer has a layer structure of heat resistant resin layer (B)/fluororesin layer (A), a layer structure of heat resistant resin layer (B)/fluororesin layer (A)/heat resistant resin layer (B) or a layer structure of fluororesin layer (A)/heat resistant resin layer (B)/fluororesin layer (A).

4. The process for producing a wiring substrate according to claim 1, wherein the fluororesin (a) has a melting point of at least 260° C.

5. The process for producing a wiring substrate according to claim 1, wherein the electrical insulator layer has a dielectric constant of from 2.0 to 3.0.

6. The process for producing a wiring substrate according to claim 1, wherein the functional groups contain at least carbonyl group-containing groups, and the carbonyl group-containing groups are at least one member selected from the group consisting of groups having a carbonyl group between carbon atoms in a hydrocarbon group, carbonate groups, carboxy groups, haloformyl groups, alkoxycarbonyl groups and acid anhydride residues.

7. The process for producing a wiring substrate according to claim 1, wherein the content of the functional groups in the fluororesin (a) is from 10 to 60,000 groups per 1×10⁶ carbon atoms in the main chain of the fluororesin (a).

8. The process for producing a wiring substrate according to claim 1, wherein the fluororesin (a) is composed of a copolymer of tetrafluoroethylene, a perfluoro(alkyl vinyl ether) and an unsaturated dicarboxylic anhydride.

9. The process for producing a wiring substrate according to claim 1, wherein the heat resistant resin (b) is composed of a polyimide.

10. A wiring substrate comprising an electrical insulator layer, a first conductor layer formed on a first surface of the electrical insulator layer and a second conductor layer formed on a second surface opposite from the first surface of the electrical insulator layer, and having a hole which opens at least from the first conductor layer through the second conductor layer and a plating layer formed on an inner wall surface of the hole; wherein
the electrical insulator layer has a multi-layered structure containing at least one fluororesin layer (A) containing a melt-moldable fluororesin (a) having at least one type to of functional groups selected from the group consisting of carbonyl group-containing groups, hydroxy groups, epoxy groups and isocyanate groups, and at least one heat resistant resin layer (B) containing a heat resistant resin (b) (excluding the fluororesin (a)), contains no reinforcing fiber substrate made of woven fabric or non-woven fabric, and has a dielectric constant of from 2.0 to 3.5 and a linear expansion coefficient of from 0 to 35 ppm/° C.; and
the following rate of change of electrical resistance as between before and after a thermal shock test is within a range of ±10%:
rate of change of electrical resistance: a rate of change of the resistance between the conductor layers on both sides of the electrical insulator layer via the plating layer after a thermal shock test of conducting 100 cycles each comprising leaving the wiring substrate in an environment of −65° C. for 30 minutes and then leaving it in an environment of 125° C. for 30 minutes, based on the resistance before the thermal shock test.

11. The wiring substrate according to claim 10, wherein the electrical insulator layer has a layer structure of heat resistant resin layer (B)/fluororesin layer (A), a layer structure of heat resistant resin layer (B)/fluororesin layer (A)/heat resistant resin layer (B) or a layer structure of fluororesin layer (A)/heat resistant resin layer (B)/fluororesin layer (A).

12. An antenna, which comprises the wiring substrate as defined in claim 10, wherein at least one of the first conductor layer and the second conductor layer is a conductor layer having an antenna pattern.
